(19) United States
(12) Patent Application Publication
(10) Pub. No.: US 2015/0198670 A1
(43) Pub. Date: Jul. 16, 2015

(54) STATE-OF-CHARGE INDICATOR

(71) Applicant: LAURA THIEL, RALEIGH, NC (US)

(72) Inventor: LAURA THIEL, RALEIGH, NC (US)

(21) Appl. No.: 14/156,126

(22) Filed: Jan. 15, 2014

(51) Int. Cl. G01R 31/36

(52) U.S. Cl. CPC G01R 31/362

(57) ABSTRACT

A pluggable state-of-charge (SOC) indicator and methods of use are disclosed. The pluggable SOC indicator includes at least one voltage input jack for connecting to a battery, at least one instance of control electronics, and at least one SOC indicator, such as a 5-bar liquid crystal display (LCD). Embodiments of the pluggable SOC indicator include, but are not limited to, a pluggable single-connector SOC indicator, a pluggable dual-connector SOC indicator, and a pluggable quad-connector SOC indicator. Further, the control electronics are programmable for any input voltage range and/or battery discharge characteristics.

### TECHNICAL FIELD

The presently disclosed subject matter relates generally to state-of-charge (SOC) indicators for batteries and more particularly to pluggable state-of-charge (SOC) indicators and methods of use thereof.

### BACKGROUND

The use of indicators for monitoring the state-of-charge (SOC) of rechargeable batteries, such as lithium ion batteries, is well known. SOC indicators often are incorporated into the battery housing itself. A built-in SOC indicator, however, operates continuously and is a constant drain on the battery that it is monitoring. Consequently, the built-in SOC indicator itself contributes to shortening the life of the battery with which it is used.

### SUMMARY

In some aspects, the presently disclosed subject matter provides an indicator device for monitoring a state of charge of one or more batteries or battery packs, the device including at least one voltage input connector configured to be electrically coupled to at least one voltage output connector of a battery or battery pack. The device further includes control electronics capable of measuring a voltage received from the at least one voltage input connector when the voltage input connector is electrically coupled to the at least one voltage output connector of the battery or battery pack to be monitored, and wherein the control electronics are programmed to process an input voltage range and/or a battery discharge characteristic to determine a state of charge. The device further includes at least one indicator which indicates the state of charge, wherein the at least one voltage input connector, the control electronics, and the at least one indicator are in electronic communication, and wherein the state of charge shown by the at least one indicator is related to the voltage measured by the control electronics.

In certain aspects, the indicator device comprises between one and four voltage input connectors, wherein the between one and four voltage input connectors are each in electronic communication with separate control electronics and separate indicators, and wherein each separate indicator in electronic communication with the between one and four voltage input connectors operate independently.

In other aspects, the presently disclosed subject matter provides a device for monitoring a state of charge of one or more batteries or battery packs, wherein the state of charge is communicated through a communications interface to a network instead of indicated through one or more indicators on the device. In certain aspects, the device is configured to communicate with a mobile device coupled to the network.

Certain aspects of the presently disclosed subject matter having been stated hereinabove, which are addressed in whole or in part by the presently disclosed subject matter, other aspects will become evident as the description proceeds when taken in connection with the accompanying Examples and Drawings as best described herein below.

### BRIEF DESCRIPTION OF THE DRAWINGS

Having thus described the presently disclosed subject matter in general terms, reference will now be made to the accompanying Drawings, which are not necessarily drawn to scale, and wherein:

FIG. 1 illustrates a perspective view of an example of a pluggable single-connector SOC indicator according to one embodiment of the presently disclosed pluggable SOC indicators;

FIG. 2 illustrates a perspective view of an example of a pluggable dual-connector SOC indicator according to another embodiment of the presently disclosed pluggable SOC indicators;

FIG. 3 illustrates a perspective view of an example of a pluggable quad-connector SOC indicator according to yet another embodiment of the presently disclosed pluggable SOC indicators;

FIG. 4 illustrates a block diagram of an example of the control electronics of the presently disclosed pluggable SOC indicators;

FIG. 5A, FIG. 5B, and FIG. 5C illustrate block diagrams of example configurations of the pluggable single-connector SOC indicator, the pluggable dual-connector SOC indicator, and pluggable quad-connector SOC indicator, wherein the indicators operate independently;

FIG. 6A and FIG. 6B illustrate block diagrams of example configurations of the pluggable dual-connector SOC indicator and the pluggable quad-connector SOC indicator, wherein the indicators do not operate independently;

FIG. 7 illustrates a perspective view of a specific example of a pluggable dual-connector SOC indicator;

FIG. 8 illustrates a perspective view and a plan view of the pluggable dual-connector SOC indicator shown in FIG. 7, absent the cover thereof;

FIG. 9 illustrates a perspective view of a printed circuit board and indicators of the pluggable dual-connector SOC indicator shown in FIG. 7;

FIG. 10 illustrates a top view of the base plate of the pluggable dual-connector SOC indicator shown in FIG. 7;

FIG. 11 and FIG. 12 illustrate end views of the base plate of the pluggable dual-connector SOC indicator shown in FIG. 7;

FIG. 13 illustrates a perspective view of a base plate of the pluggable dual-connector SOC indicator shown in FIG. 7;

FIG. 14 illustrates a top perspective view and a bottom perspective view of a cover of the pluggable dual-connector SOC indicator shown in FIG. 7;

FIG. 15 illustrates a top view, a side view, an end view, and a bottom view of the cover of the pluggable dual-connector SOC indicator shown in FIG. 7;

FIG. 16 shows an example of the pluggable dual-connector SOC indicator shown in FIG. 7 when in use;

FIG. 17 illustrates a flow diagram of an example of a method of using the presently disclosed pluggable SOC indicator in one configuration;

FIG. 18 illustrates a flow diagram of an example of a method of using the presently disclosed pluggable dual-connector SOC indicator shown in FIG. 7;

FIG. 19 illustrates a block diagram of an example of an SOC system that includes a mobile application for use with the presently disclosed pluggable SOC indicators;

FIG. 20 illustrates a block diagram of an example of the control electronics of the presently disclosed pluggable SOC indicators that is capable of communicating with the mobile application; and

FIG. 21 illustrates a block diagram of another example of the control electronics of the presently disclosed pluggable SOC indicators that is capable of communicating with the mobile application.

### DETAILED DESCRIPTION

The presently disclosed subject matter now will be described more fully hereinafter with reference to the accompanying Drawings, in which some, but not all embodiments of the presently disclosed subject matter are shown. Like numbers refer to like elements throughout. The presently disclosed subject matter may be embodied in many different forms and should not be construed as limited to the embodiments set forth herein; rather, these embodiments are provided so that this disclosure will satisfy applicable legal requirements. Indeed, many modifications and other embodiments of the presently disclosed subject matter set forth herein will come to mind to one skilled in the art to which the presently disclosed subject matter pertains having the benefit of the teachings presented in the foregoing descriptions and the associated Drawings. Therefore, it is to be understood that the presently disclosed subject matter is not to be limited to the specific embodiments disclosed and that modifications and other embodiments are intended to be included within the scope of the appended claims.

In some embodiments, the presently disclosed subject matter provides a pluggable state-of-charge (SOC) indicator. In one embodiment, the pluggable SOC indicator supports one voltage input, hereafter called the pluggable single-connector SOC indicator. The pluggable single-connector SOC indicator is designed for use with one type of battery or battery pack. Namely, a slip-on, non-locking connector of the pluggable single-connector SOC indicator is coupled to a mating slip-on, non-locking connector of the battery or battery pack. Then, the charge status of the battery or battery pack is provided on an indicator of the pluggable single-connector SOC indicator.

In another embodiment, the pluggable SOC indicator supports two voltage inputs, hereafter called the pluggable dual-connector SOC indicator. The pluggable dual-connector SOC indicator is designed for use with two different types of batteries or battery packs. Namely, a first slip-on, non-locking connector of the pluggable dual-connector SOC indicator is coupled to a mating slip-on, non-locking connector of a first battery or battery pack. Then, the charge status of the first battery or battery pack is provided on a first indicator of the pluggable dual-connector SOC indicator. Additionally, a second slip-on, non-locking connector of the pluggable dual-connector SOC indicator is coupled to a mating slip-on, non-locking connector of a second battery or battery pack. Then, the charge status of the second battery or battery pack is provided on a second indicator of the pluggable dual-connector SOC indicator. The first indicator and the second indicator of the pluggable dual-connector SOC indicator operate independently. In another embodiment, the connector plugs also can be locking or semi-locking, depending on the battery connection to be joined. The connector also can be in the form of a receptacle. Any connectors may present with either pins or sockets.

In yet another embodiment, the pluggable SOC indicator supports four voltage inputs, hereafter called the pluggable quad-connector SOC indicator. The pluggable quad-connector SOC indicator is designed for use with four different types of batteries or battery packs. Namely, a first slip-on, non-locking connector of the pluggable quad-connector SOC indicator is coupled to a mating slip-on, non-locking connector of a first battery or battery pack. Then, the charge status of the first battery or battery pack is provided on a first indicator of the pluggable quad-connector SOC indicator. A second slip-on, non-locking connector of the pluggable quad-connector SOC indicator is coupled to a mating slip-on, non-locking connector of a second battery or battery pack. Then, the charge status of the second battery or battery pack is provided on a second indicator of the pluggable quad-connector SOC indicator. A third slip-on, non-locking connector of the pluggable quad-connector SOC indicator is coupled to a mating slip-on, non-locking connector of a third battery or battery pack. Then, the charge status of the third battery or battery pack is provided on a third indicator of the pluggable quad-connector SOC indicator. Further, a fourth slip-on, non-locking connector of the pluggable quad-connector SOC indicator is coupled to a mating slip-on, non-locking connector of a fourth battery or battery pack. Then, the charge status of the fourth battery or battery pack is provided on a fourth indicator of the pluggable quad-connector SOC indicator. The first indicator, second indicator, third indicator, and fourth indicator of the pluggable quad-connector SOC indicator operate independently.

The presently disclosed pluggable SOC indicator is not limited to supporting one, two, or four voltage inputs. The pluggable single-connector SOC indicator, the pluggable dual-connector SOC indicator, and the pluggable quad-connector SOC indicator are exemplary only. The presently disclosed pluggable SOC indicator can support any number of voltage inputs that can be implemented in a practical manner. Namely, the presently disclosed pluggable SOC indicator can be a pluggable 1-to-n SOC indicator, wherein ‘n’ is the number of connectors. In some embodiments, the presently disclosed pluggable SOC can support between one and four voltage inputs, including one, two, three, or four voltage inputs.

One aspect of the presently disclosed pluggable SOC indicators, such as the pluggable single-connector SOC indicator, the pluggable dual-connector SOC indicator, and the pluggable quad-connector SOC indicator, is that they are under power only when plugged into the battery or battery pack to be monitored. Therefore, the presently disclosed pluggable SOC indicators present a load or drain on the battery or battery pack to be monitored only during the brief period of time in which they are plugged in and the SOC is indicated.

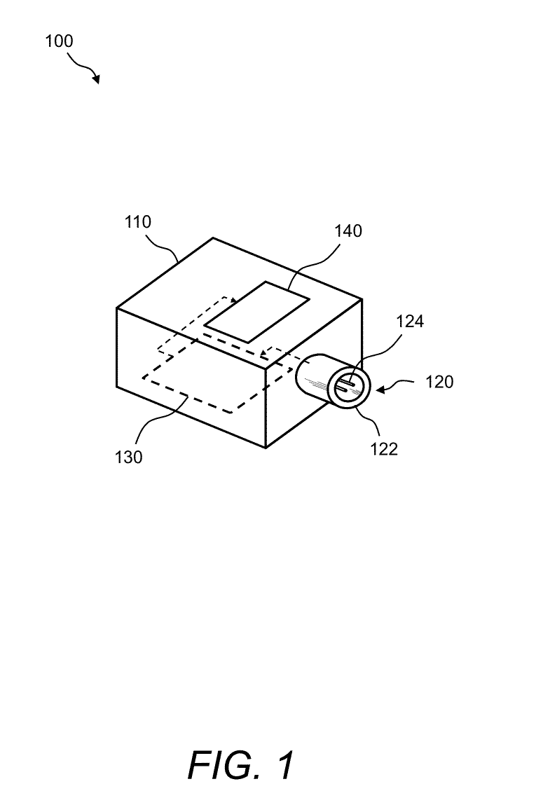

Referring now to FIG. 1, is a perspective view of an example of a pluggable single-connector SOC indicator 100 according to one embodiment of the presently disclosed pluggable SOC indicators. The pluggable single-connector SOC indicator 100 includes a housing 110. Mounted on one end of the housing 110 is a voltage input jack 120. The voltage input jack 120 includes a shroud 122 and one or more pins 124. The shroud 122 can be formed of metal or plastic that is wear resistant or a so called “barrel” connector.

The pluggable single-connector SOC indicator 100 further includes certain control electronics 130 for sensing the voltage received from the voltage input jack 120 when the voltage input jack 120 is electrically coupled to a voltage output connector of an external battery or battery pack (not shown) of interest. In some embodiments, the voltage input jack 120 is electrically coupled to the voltage output connector of the external battery or battery pack (not shown) of interest through a mechanical connection (also referred to herein as “electro-mechanically” connected). The control electronics 130 then drive an indicator 140, which shows the state of charge. The voltage input jack 120 can be any type of connector needed to electrically couple to a voltage output connecter (not shown) of the external battery or battery pack of interest. Further, the voltage input jack 120 is configured to be reversibly electrically coupled or electro-mechanically connected to the voltage output connector of the battery or battery pack.

Accordingly, in one example, the voltage input jack 120 and the voltage output connecter (not shown) of the external battery or battery pack are both a slip-on, non-locking type of connector. In one example, the battery connector is a female-type of connector that is press-fitted onto the voltage input jack 120, which is a male-type of connector. In another example, the voltage input jack 120 is a female-type of connector that is press-fitted onto the battery connector, which is a male-type of connector. Similarly, pins and sockets can be selected to mate with the output connector of the battery of interest. Generally, any permutation of pins, sockets or pinout corresponding to those of the battery of interest can be used.

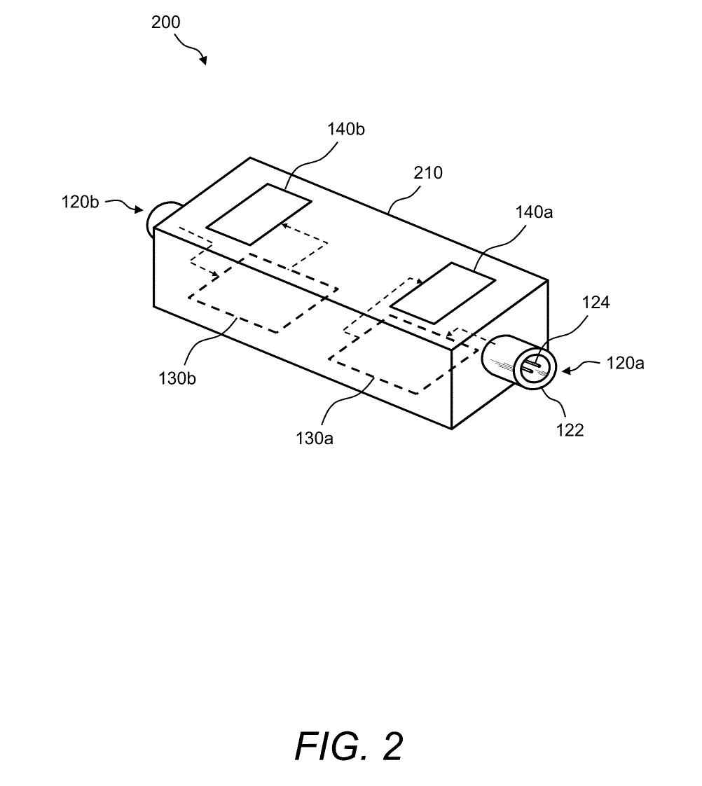

FIG. 2 illustrates a perspective view of an example of a pluggable dual-connector SOC indicator 200 according to another embodiment of the presently disclosed pluggable SOC indicators. The pluggable dual-connector SOC indicator 200 is substantially the same as pluggable single-connector SOC indicator 100 of FIG. 1 except that it supports two instances of the voltage input jack 120, two instances of the control electronics 130, and two instances of the indicator 140. The housing 110 is sized and shaped accordingly. For example, in pluggable dual-connector SOC indicator 200, a voltage input jack 120a is mounted on one end of the housing 110, while a voltage input jack 120b is mounted on the opposite end of the housing 110. Further, the voltage input jack 120a feeds the control electronics 130a, which then drives an indicator 140a. The voltage input jack 120b feeds the control electronics 130b, which then drives an indicator 140b.

The voltage input jack 120a, the control electronics 130a, and the indicator 140a operate separately and independently from the voltage input jack 120b, the control electronics 130b, and the indicator 140b. Further, the voltage input jack 120a and the voltage input jack 120b can be different depending on the type of battery or battery pack to be mated thereto. Namely, the voltage input jack 120a, the control electronics 130a, and the indicator 140a are tailored for monitoring the SOC of one type of battery or battery pack, while the voltage input jack 120b, the control electronics 130b, and the indicator 140b are tailored for monitoring the SOC of another type of battery or battery pack. In one example, the control electronics 130a are programmed to process a certain input voltage range and/or battery discharge characteristic, while the control electronics 130b are programmed to process a different input voltage range and/or battery discharge characteristic.

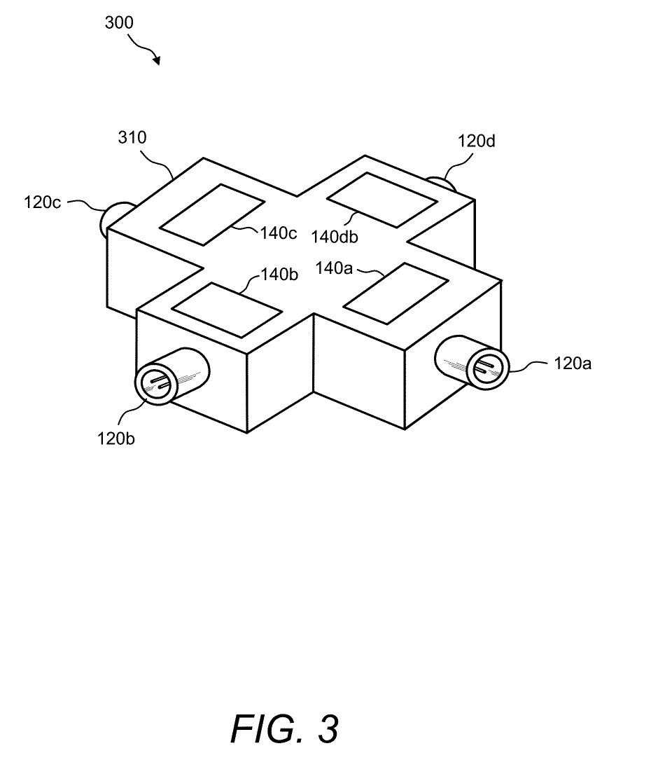

FIG. 3 illustrates a perspective view of an example of a pluggable quad-connector SOC indicator 300 according to yet another embodiment of the presently disclosed pluggable SOC indicators. The pluggable quad-connector SOC indicator 300 is substantially the same as pluggable single-connector SOC indicator 100 of FIG. 1 except that it supports four instances of the voltage input jack 120, four instances of the control electronics 130, and four instances of the indicator 140. The housing 110 is sized and shaped accordingly to accommodate each of the aforementioned elements. For example, the pluggable quad-connector SOC indicator 300 is formed in a cross-configuration that includes a voltage input jack 120a, a voltage input jack 120b, a voltage input jack 120c, and a voltage input jack 120d, as shown Further, the voltage input jack 120a feeds control electronics 130a, which then drives an indicator 140a. The voltage input jack 120b feeds control electronics 130b, which then drives an indicator 140b. The voltage input jack 120c feeds control electronics 130c, which then drives an indicator 140c. The voltage input jack 120d feeds control electronics 130d, which then drives an indicator 140d.

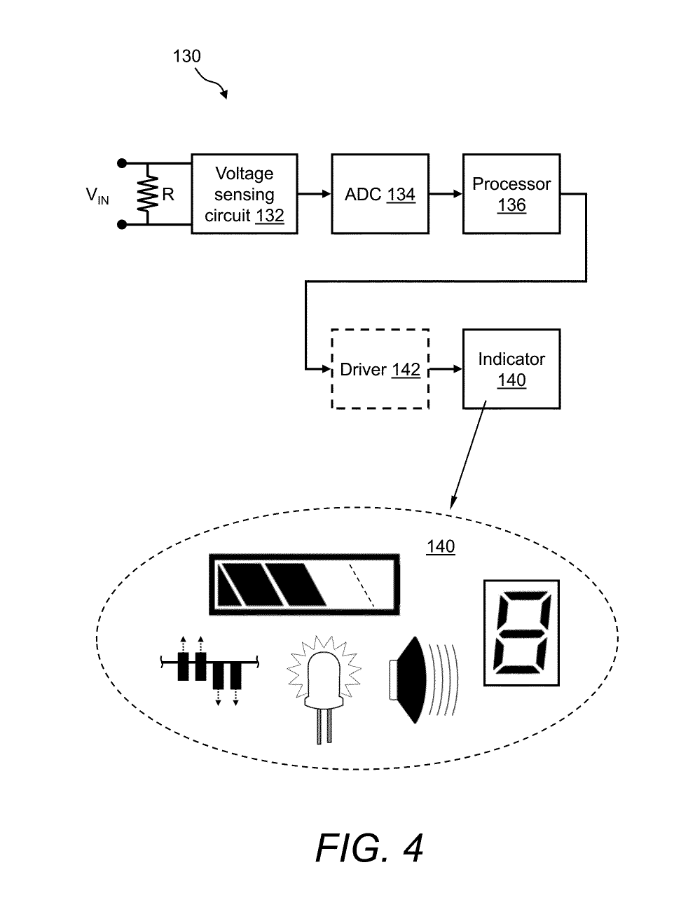

In some embodiments, the four voltage input jacks 120, the four control electronics 130, and the four indicators 140 operate separately and independently from each other. Further, the voltage input jacks 120a, 120b, 120c, and 120d can be different depending on the type of battery or battery pack to be mated thereto. Namely, the voltage input jack 120a, the control electronics 130a, and the indicator 140a are tailored for monitoring the SOC of one type of battery or battery pack; the voltage input jack 120b, the control electronics 130b, and the indicator 140b are tailored for monitoring the SOC of another type of battery or battery pack; the voltage input jack 120c, the control electronics 130c, and the indicator 140c are tailored for monitoring the SOC of yet another type of battery or battery pack, while the voltage input jack 120d, the control electronics 130db, and the indicator 140db are tailored for monitoring the SOC of still another type of battery or battery pack. In one example, the control electronics 130a, 130b, 130c, and 130d are programmed to process different input voltage ranges and/or battery discharge characteristics, respectively. More details of an example of the control electronics 130 are shown and described herein below with reference to FIG. 4.

FIG. 4 illustrates a block diagram of an example of one instance of the control electronics 130 of the presently disclosed pluggable SOC indicators. In this example, the control electronics 130 includes a voltage sensing circuit 132, an analog-to-digital converter (ADC) 134, a processor 136, the indicator 140, and optionally a driver 142.

The voltage sensing circuit 132 can be any standard voltage sensing circuit, such as those found in volt meters. An input voltage V_{IN} is supplied via the voltage input jack 120. The voltage sensing circuit 132 can be designed to sense any direct current (DC) voltage in the range of, for example, from about 0 volts DC to about 50 volts DC. The voltage sensing circuit 132 can include standard amplification or de-amplification functions for generating an analog voltage that correlates to the amplitude of the input voltage V_{IN} that is present. The ADC 134 receives the analog voltage from the voltage sensing circuit 132 and performs a standard analog-to-digital conversion.

The processor 136 manages the overall operations of the presently disclosed pluggable SOC indicator. The processor 136 can be any controller, microcontroller, or microprocessor that is capable of processing program instructions.

The indicator 140 can be any visual, audible, or tactile mechanism for indicating the state of charge of the battery or battery pack with which the presently disclosed pluggable SOC indicator is used. One example of a visual indicator is a 5-bar liquid crystal display (LCD), wherein five bars indicates greatest charge and one bar or one bar flashing indicates least charge. Another example of a visual indicator is a seven-segment numeric LCD, wherein the number 5 indicates greatest charge and the number 1 or the number 1 flashing indicates least charge. Yet another example of a visual indicator is a set of light-emitting diodes (LEDs) (e.g., 5 LEDs), wherein five lit LEDs indicates greatest charge and one lit LED or one lit LED flashing indicates least charge.

One example of an audible indicator is any sounds via an audio speaker, such as beeping sounds, wherein five beeps indicates greatest charge and one beep indicates least charge. Another example of an audible indicator is vibration sounds via any vibration mechanism (e.g., vibration motor used in mobile phones), wherein five vibration sounds indicates greatest charge and one vibration sound indicates least charge.

One example of a tactile indicator is any vibration mechanism (e.g., vibration motor used in mobile phones), wherein five vibrations indicate greatest charge and one vibration indicate least charge. Another example of a tactile indicator is a set of pins that rise up and down to be felt in Braille-like fashion, wherein five raised pins indicates greatest charge and one raised pin indicates least charge.

In one example, the processor 136 is able to drive indicator 140 directly. For example, the processor 136 may be able to drive directly a 5-bar LCD or a seven-segment numeric LCD. In another example, however, the processor 136 is not able to drive indicator 140 directly. In this case, the driver 142 is provided, wherein the driver 142 is specific to the type of indicator 140 used in the control electronics 130.

Additionally, the processor 136 includes internal programmable functions for programming the expected range of the input voltage V_{IN} and the correlation of the value the input voltage V_{IN} to what is indicated at the indicator 140. In other words, the discharge curve of the battery or battery pack of interest can be correlated to what is indicated at indicator 140. The processor 136 can be programmed, for example, based on percent discharged or on an absolute value present at the input voltage V_{IN}.

By way of example, the battery or battery pack of interest is a 24-volt battery and the indicator 140 is a 5-bar LCD. In one example, the processor 136 may be programmed as follows: V_{IN}=24 v−21.01 v, then display 5 bars; V_{IN}=21 v−18.01 v, then display 4 bars; V_{IN}=18 v−16.01 v, then display 3 bars; V_{IN}=16 v−14.01 v, then display 2 bars; and V_{IN}=below 14.01 v, then display 1 bar.

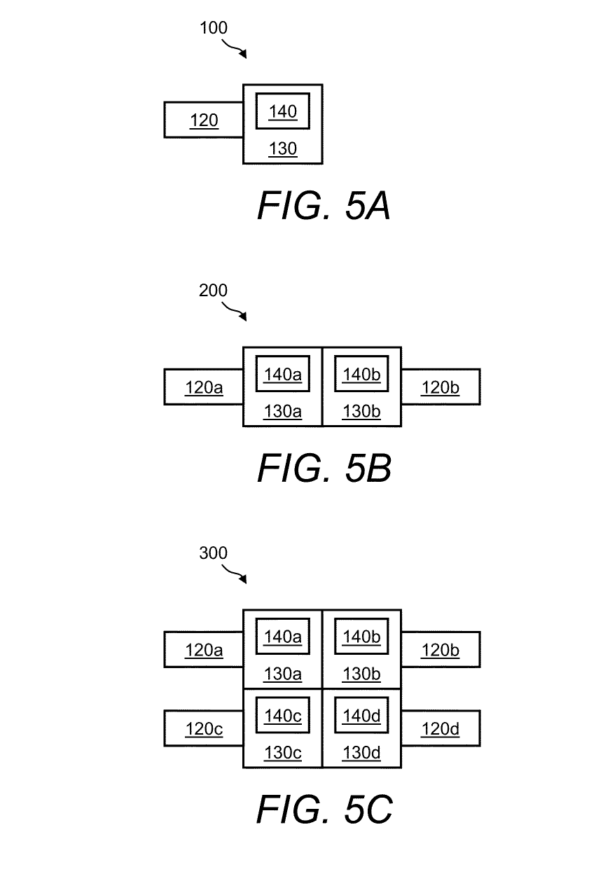

FIG. 5A, FIG. 5B, and FIG. 5C illustrate block diagrams of example configurations of the pluggable single-connector SOC indicator 100, the pluggable dual-connector SOC indicator 200, and pluggable quad-connector SOC indicator 300, wherein the indicators operate independently. Namely, the modularity of the presently disclosed pluggable SOC indicators is shown in FIG. 5A, FIG. 5B, and FIG. 5C.

For example, FIG. 5A shows the pluggable single-connector SOC indicator 100 that includes the one voltage input jack 120 supplying one instance of the control electronics 130. FIG. 5B shows the pluggable dual-connector SOC indicator 200 that includes the voltage input jack 120a supplying the control electronics 130a and the voltage input jack 120b supplying the control electronics 130b, wherein the control electronics 130a and 130b operate separately and independently. In one example, the voltage input jack 120a and the control electronics 130a support a 24-volt battery and the voltage input jack 120b and the control electronics 130b support a 20-volt battery. FIG. 5C shows the pluggable dual-connector SOC indicator 200 that includes the voltage input jack 120a supplying the control electronics 130a, the voltage input jack 120b supplying the control electronics 130b, the voltage input jack 120c supplying the control electronics 130c, and the voltage input jack 120d supplying the control electronics 130d, wherein the control electronics 130a, 130b, 130c, and 130d operate separately and independently. In one example, the voltage input jack 120a and the control electronics 130a support a 24-volt battery, the voltage input jack 120b and the control electronics 130b support a 20-volt battery, the voltage input jack 120c and the control electronics 130c support a 16-volt battery, and the voltage input jack 120d and the control electronics 130d support a 12-volt battery.

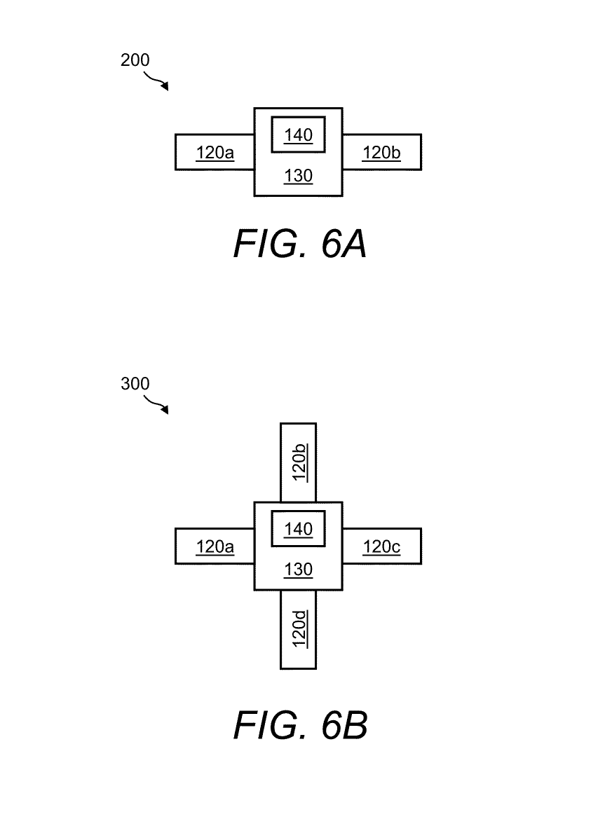

FIG. 6A and FIG. 6B illustrate block diagrams of example configurations of the pluggable dual-connector SOC indicator 200 and the pluggable quad-connector SOC indicator 300, wherein the indicators do not operate independently. Namely, in these configurations, multiple voltage input jacks 120 supply one instance of the control electronics 130 and one instance of the indicator 140. For example and referring now to FIG. 6A, the control electronics 130 and the indicator 140 are used in common with both voltage input jacks 120a and 120b. The voltage input jacks 120a and 120b are connected in parallel at the input voltage V_{IN} of the control electronics 130. Referring now to FIG. 6B, the control electronics 130 and the indicator 140 are used in common with the four voltage input jacks 120a, 120b, 120c, and 120d. The voltage input jacks 120a, 120b, 120c, and 120d are connected in parallel at the input voltage V_{IN} of the control electronics 130.

Because the expected voltage range at the multiple voltage input jacks 120 can be different, the programmable function of the processor 136 can differ for each of the multiple voltage input jacks 120. Therefore, in FIG. 6A and FIG. 6B, the voltage sensing circuit 132 can provide a select line to the processor 136 for each of the multiple voltage input jacks 120. For example, in FIG. 6A the voltage sensing circuit 132 provides two select lines to the processor 136 for uniquely identifying the voltage input jack 120a or 120b when in use, while in FIG. 6B the voltage sensing circuit 132 provides four select lines to the processor 136 for uniquely identifying the voltage input jack 120a, 120b, 120c, or 120d when in use. Then, based on the state of the select lines, the program function that correlates to the voltage input jack 120 that is in use is automatically selected. In one example, when the voltage input jack 120a is detected the 24-volt battery program function in the processor 136 is automatically selected, when the voltage input jack 120b is detected the 20-volt battery program function in the processor 136 is automatically selected, when voltage input jack 120c is detected the 16-volt battery program function in the processor 136 is automatically selected, and when the voltage input jack 120d is detected the 12-volt battery program function in the processor 136 is automatically selected.

A limitation of the configuration shown in FIG. 6A and FIG. 6B as compared with the configuration shown in FIG. 5B and FIG. 5C, however, is that only one voltage input jack 120 can be in use at any given time.

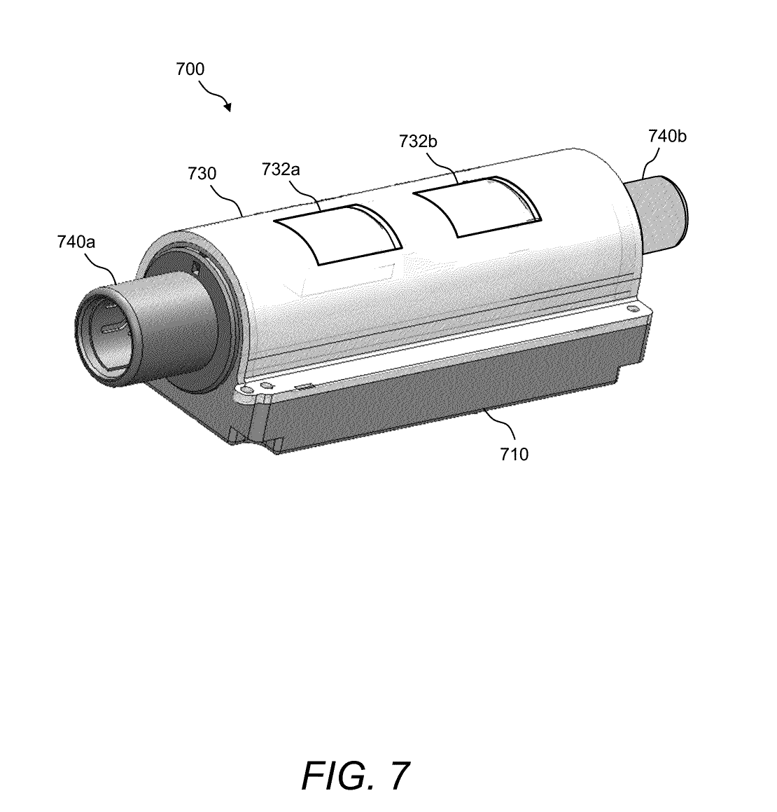

More details of an example of the pluggable dual-connector SOC indicator 200 configured according to FIG. 5B are shown and described herein below with reference to FIG. 7 through FIG. 16. Namely, FIG. 7 illustrates a perspective view of a pluggable dual-connector SOC indicator 700, which is one example implementation of the pluggable dual-connector SOC indicator 200 of FIG. 2 that is configured according to FIG. 5B.

In this example, the pluggable dual-connector SOC indicator 700 includes a base plate 710 and a cover 730. The cover 730 further includes two viewing windows 732 (e.g., viewing windows 732a and 732b) through which the user can view the SOC indicators 140. Mounted on the two ends of the base plate 710 are voltage input jacks 740a and 740b, respectively. In this example, the voltage input jacks 740a and 740b are different, such as different size (e.g., length and diameter) and pin configuration.

The length of the base plate 710 and the cover 730 of the pluggable dual-connector SOC indicator 700 is, for example, about 3 inches. The width of the base plate 710 and the cover 730 of the pluggable dual-connector SOC indicator 700 is, for example, about 1.5 inches. The overall height of the pluggable dual-connector SOC indicator 700 is, for example, about 1.2 inches. The overall length of the pluggable dual-connector SOC indicator 700 (including the voltage input jacks 740a and 740b) is, for example, about 4 inches.

The base plate 710 and the cover 730 can be formed of any lightweight, rigid material, such as, but not limited to, aluminum and molded plastic. The base plate 710 and the cover 730 can be formed of the same or of different materials. In one example, the base plate 710 is formed of aluminum and the cover 730 is formed of molded plastic.

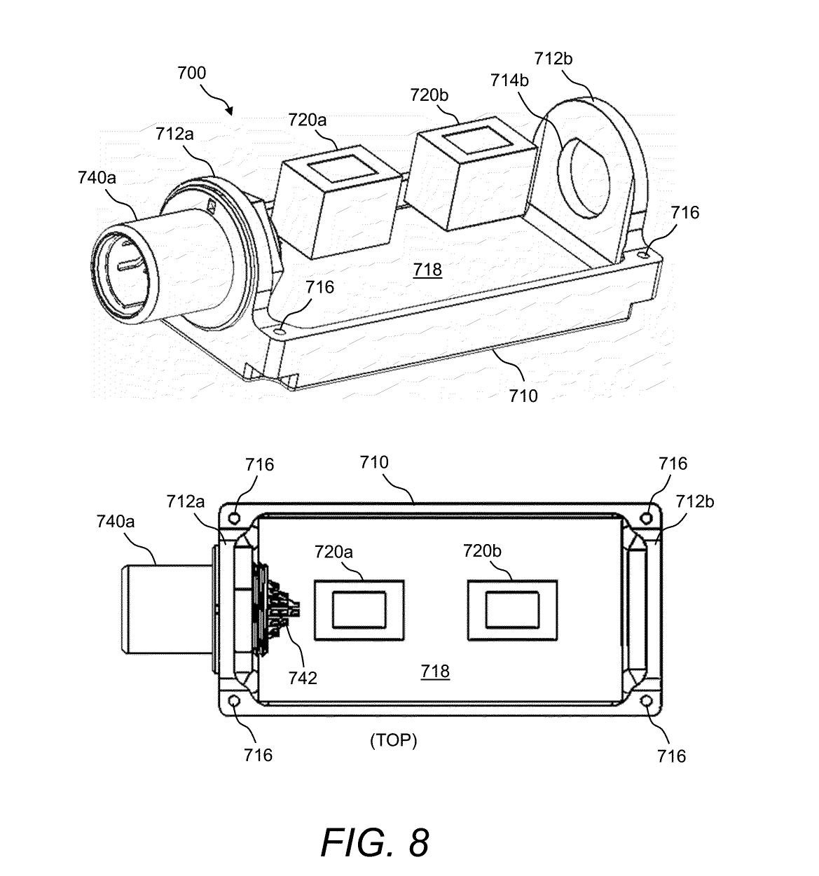

Referring now to FIG. 8 is a perspective view and a plan view of the pluggable dual-connector SOC indicator 700 of FIG. 7, absent the cover 730 and revealing more details thereof. Namely, the base plate 710 includes an end plate 712a and an end plate 712b, wherein the end plate 712a is designed to receive voltage input jack 740a and the end plate 712b is designed to receive voltage input jack 740b (not shown in FIG. 8). There is, for example, an opening 716 at each corner of the base plate 710. Openings 716 are used for fastening the cover 730 to the base plate 710 via screws, e.g., if opening 716 is a threaded hole, pins, lock pins, push pins, and other methods of fastening the cover (not shown).

Installed inside of the base plate 710 is a printed circuit board (PCB) 718 on which two instances of control electronics 130 is implemented (e.g., control electronics 130a and 130b, not shown). In one example, the control electronics 130a is programmed for a 24-volt battery and the control electronics 130b is programmed for a 20-volt battery.

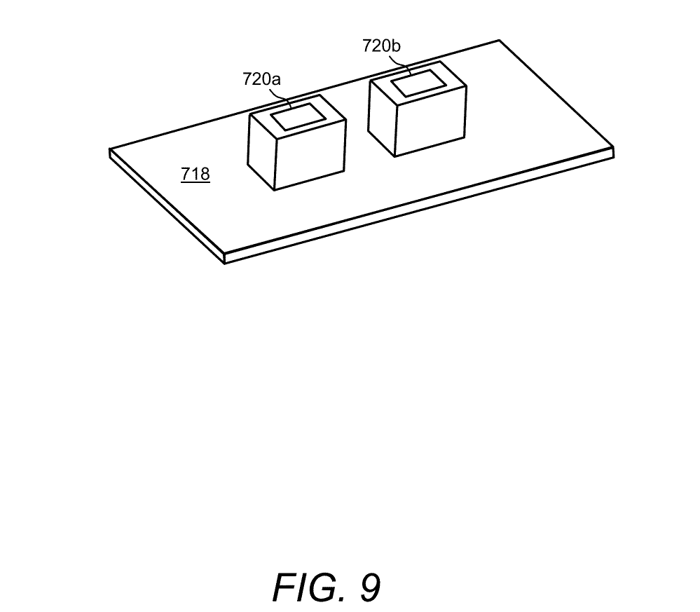

Mounted atop the PCB 718 are two 5-bar LCDs 720 (e.g., 5-bar LCDs 720a and 720b), which are examples of indicators 140. Further, the voltage input jack 740a includes a configuration of pins 742 that are electrically connected to the control electronics 130 on the PCB 718. Referring now to FIG. 9 is another view of the PCB 718 and the 5-bar LCDs 720a and 720b of the pluggable dual-connector SOC indicator 700 of FIG. 7.

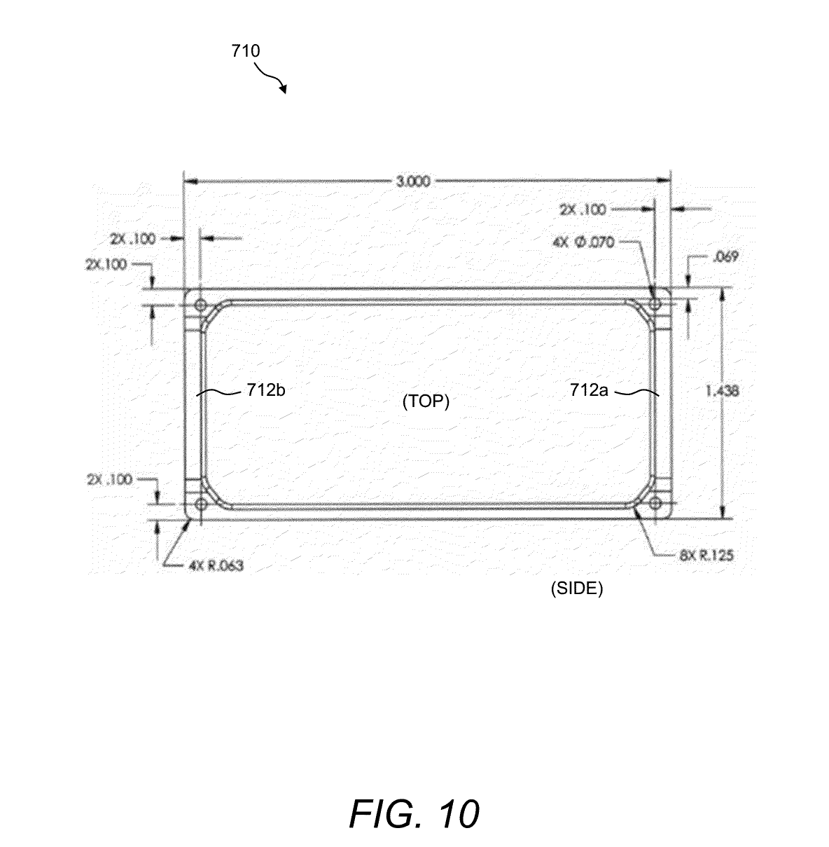

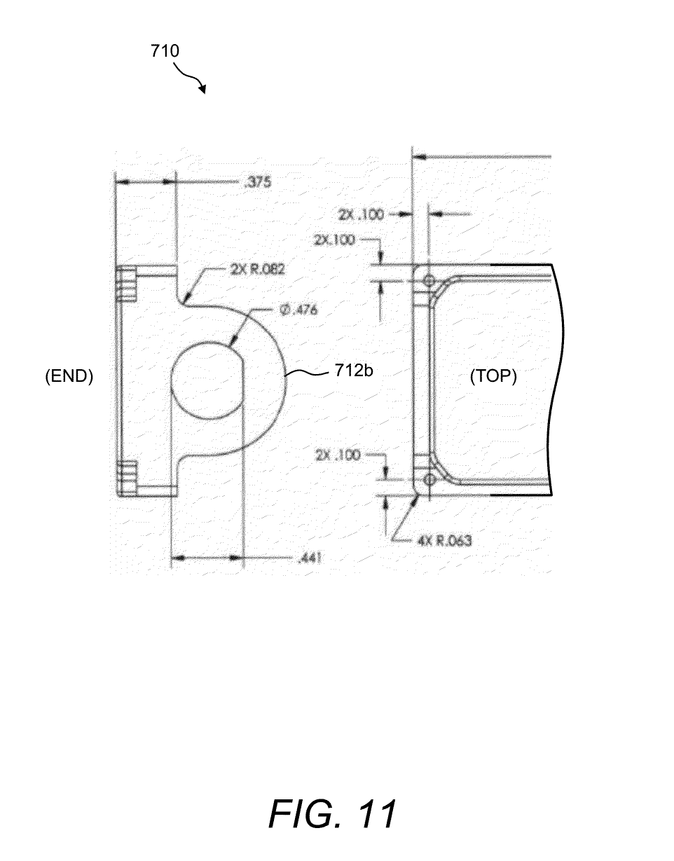

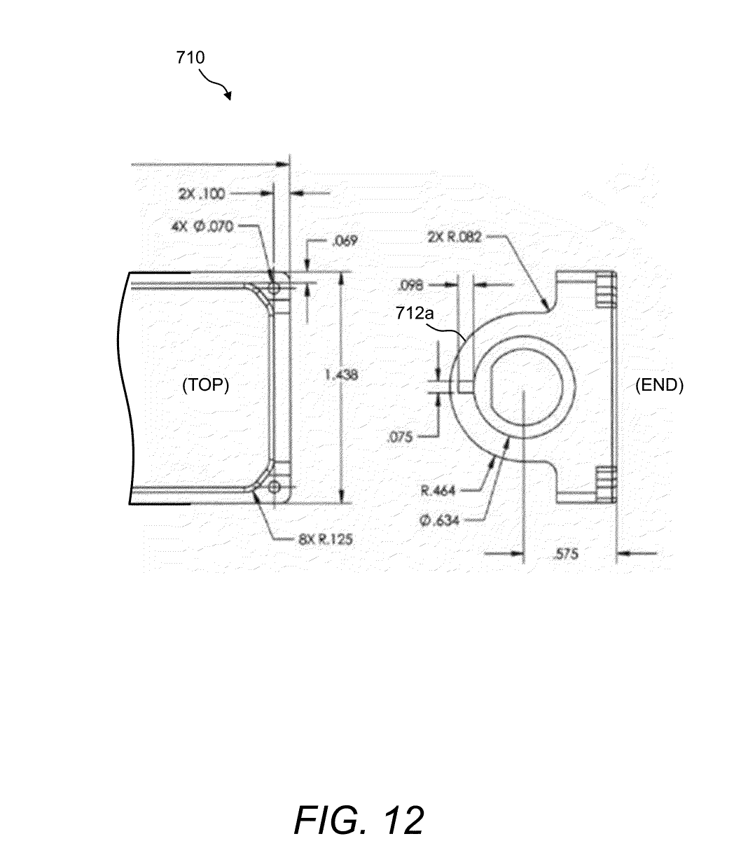

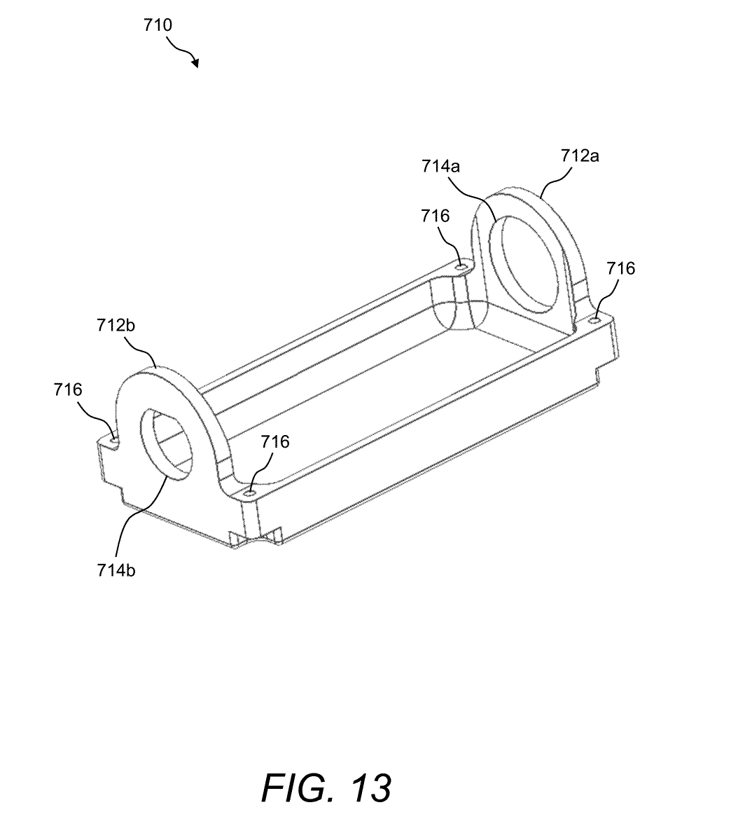

Referring now to FIG. 10, FIG. 11, FIG. 12 and FIG. 13 are various views of an example of the base plate 710 of the pluggable dual-connector SOC indicator 700 of FIG. 7, showing more details and example dimensions thereof.

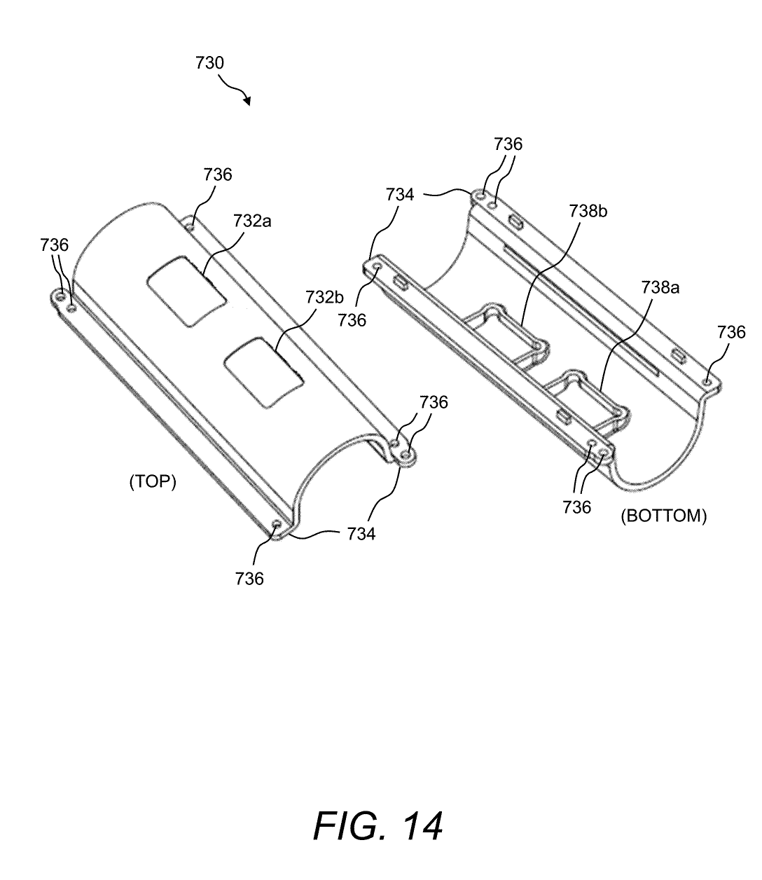

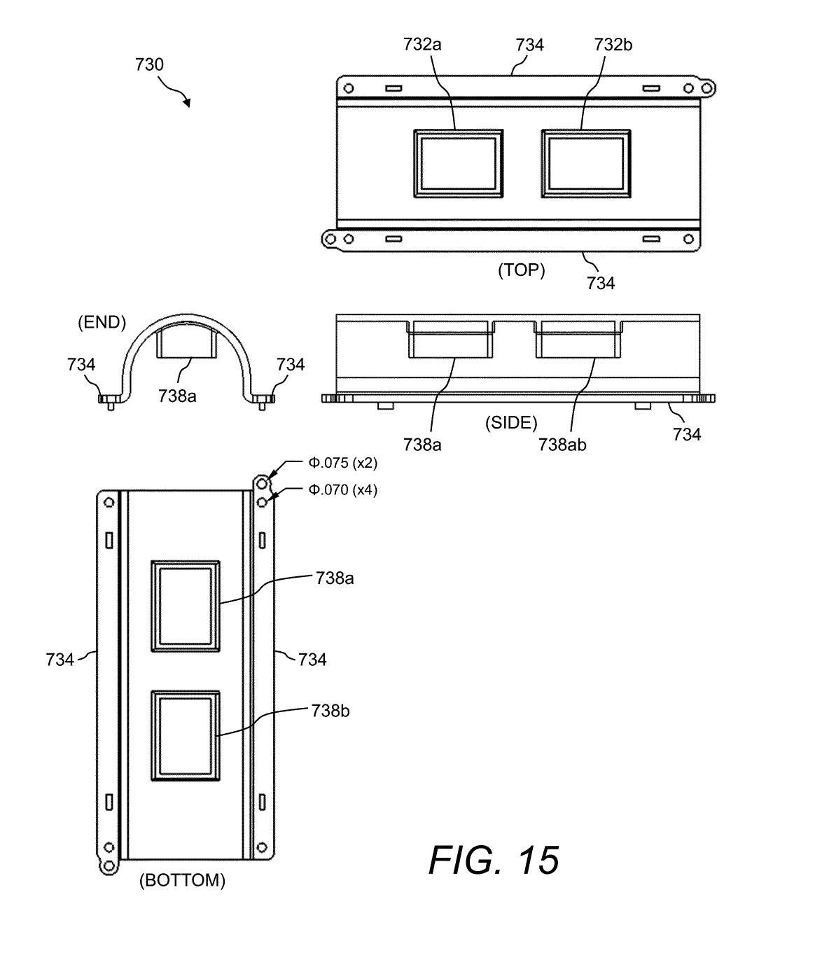

Referring now to FIG. 14 and FIG. 15 are various views of an example of the cover 730 of the pluggable dual-connector SOC indicator 700 of FIG. 7, showing more details thereof. More specifically, the cover 730 includes two side rails 734 that run along the length thereof. The two side rails 734 are designed to fit atop the edges of the base plate 710. Multiple holes 736 are provided in the two side rails 734, wherein the holes 736 can be aligned with the threaded holes 716 in the base plate 710 and wherein screws (not shown) can be used to fasten the cover 730 to the base plate 710. Additionally, a pair of alignment features 738 (e.g., alignment features 738a and 738b) are provided on the inside of the cover 730. Namely, alignment feature 738a is used to align the viewing window 732a of the cover 730 with the 5-bar LCD 720a on the PCB 718 (see FIG. 9). Likewise, alignment feature 738b is used to align the viewing window 732b of the cover 730 with the 5-bar LCD 720b on the PCB 718 (see FIG. 9).

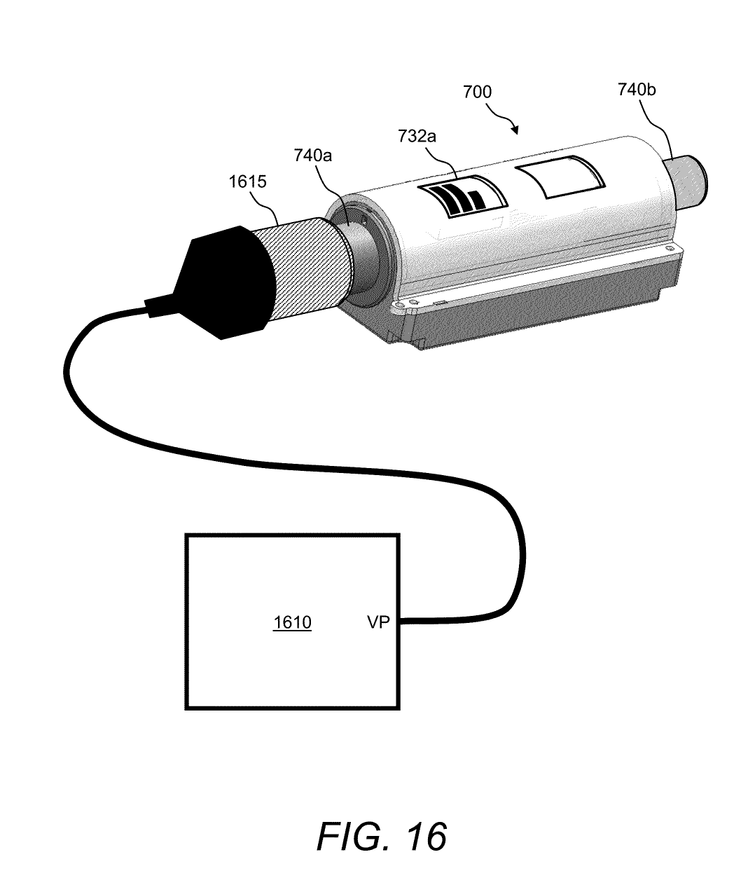

FIG. 16 shows a view (not to scale) of an example of the pluggable dual-connector SOC indicator 700 when in use. For example, FIG. 16 shows a battery or battery pack 1610, which can be any rechargeable battery or battery pack. The battery or battery pack 1610 includes a voltage out port VP. The voltage out port VP can be used by the pluggable dual-connector SOC indicator 700 for monitoring the state of charge of the battery or battery pack 1610. In this example, a connector 1615 (e.g., a slip-on, non-locking connector) is provided at the voltage out port VP of the battery or battery pack 1610.

The connector 1615 can be press-fitted upon, for example, the voltage input jack 740a of the pluggable dual-connector SOC indicator 700. In this example, the processor 136 of the control electronics 130a of the pluggable dual-connector SOC indicator 700 is programmed according to the specifications of the battery or battery pack 1610. Further, the type of voltage input jack 740a installed in the pluggable dual-connector SOC indicator 700 corresponds to the type of connector 1615 of the battery or battery pack 1610. When the pluggable dual-connector SOC indicator 700 is plugged into the connector 1615 of the battery or battery pack 1610, the state of charge of the battery or battery pack 1610 displayed on the 5-bar LCD 720a and is visible in the viewing window 732a, wherein the state of charge is displayed according to the programmed functions of the pluggable dual-connector SOC indicator 700.

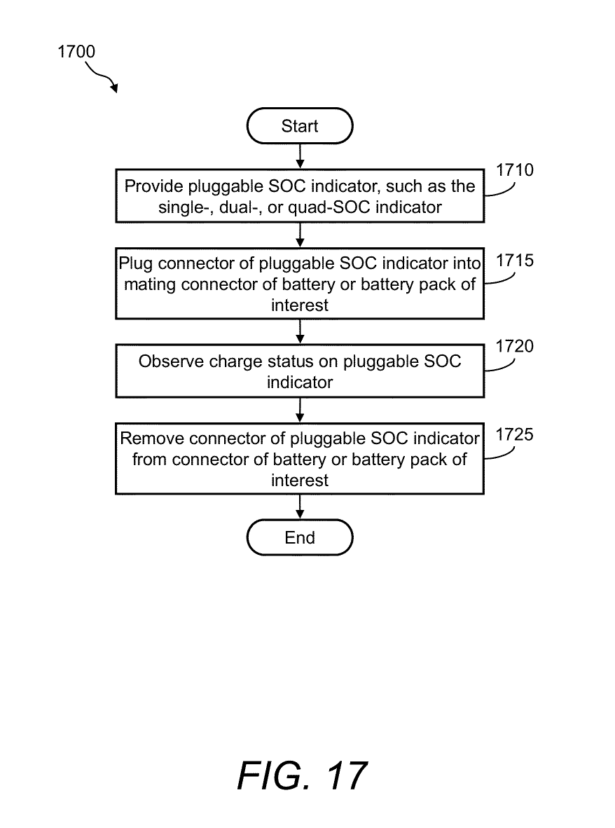

FIG. 17 illustrates a flow diagram of an example of a method 1700 of using the presently disclosed pluggable SOC indicator according to a simplest configuration. The method 1700 may include, but is not limited to, the following steps.

At a step 1710, a pluggable single, dual, or quad SOC indicator is provided. In one example, the pluggable dual-connector SOC indicator 700 that is described with reference to FIG. 7 through FIG. 16 is provided.

At a step 1715, the voltage input connector of the pluggable SOC indicator is plugged into the mating connector (i.e., a voltage output connector) of the battery or battery pack of interest. For example, a user plugs the voltage input jack 740a of the pluggable dual-connector SOC indicator 700 into the voltage output connector of the battery or battery pack of interest, such as the connector 1615 of the battery or battery pack 1610.

At a step 1720, the charge status of the battery or battery pack of interest is observed on the pluggable SOC indicator. For example, the user observes 1, 2, 3, 4, or 5 bars, or any fractions thereof, in the viewing window 732a of the pluggable dual-connector SOC indicator 700.

At a step 1725, the connector of pluggable SOC indicator is removed from the connector of battery or battery pack of interest. For example, upon satisfactorily observing the charge status of the battery or battery pack of interest, the user removes the voltage input jack 740a of the pluggable dual-connector SOC indicator 700 from the mating connector of the battery or battery pack of interest, such as from the connector 1615 of the battery or battery pack 1610.

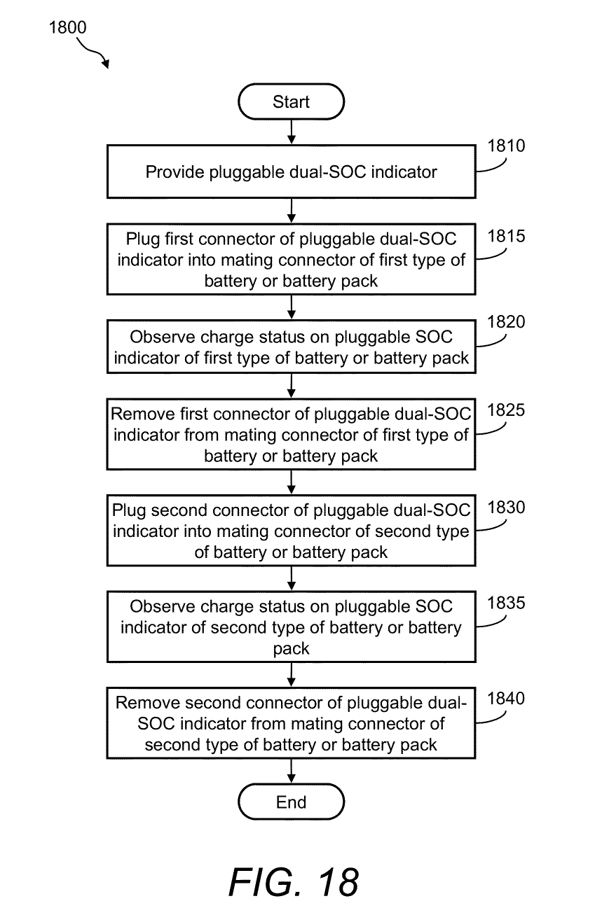

FIG. 18 illustrates a flow diagram of an example of a method 1800 of using the presently disclosed pluggable dual-connector SOC indicator 700. The method 1800 may include, but is not limited to, the following steps.

At a step 1810, the pluggable dual-connector SOC indicator 700 that is described with reference to FIG. 7 through FIG. 16 is provided.

At a step 1815, the first connector of pluggable dual-connector SOC indicator 700 is plugged into the mating connector of a first type of battery or battery pack. For example, a user plugs the voltage input jack 740a of the pluggable dual-connector SOC indicator 700 into the mating connector of a 24-volt battery.

At a step 1820, the charge status of the first type of battery or battery pack of interest is observed on the pluggable dual-connector SOC indicator 700. For example, the user observes 1, 2, 3, 4, or 5 bars, or any fractions thereof, in the viewing window 732a of the pluggable dual-connector SOC indicator 700, which is the charge status of the 24-volt battery.

At a step 1825, the first connector of pluggable dual-connector SOC indicator 700 is removed from the connector of the first type of battery or battery pack. For example, upon satisfactorily observing the charge status of the 24-volt battery, the user removes the voltage input jack 740a of the pluggable dual-connector SOC indicator 700 from the mating connector of the 24-volt battery.

At a step 1830, the second connector of pluggable dual-connector SOC indicator 700 is plugged into the mating connector of a second type of battery or battery pack. For example, a user plugs the voltage input jack 740b of the pluggable dual-connector SOC indicator 700 into the mating connector of a 20-volt battery.

At a step 1835, the charge status of the second type of battery or battery pack of interest is observed on the pluggable dual-connector SOC indicator 700. For example, the user observes 1, 2, 3, 4, or 5 bars, or any fractions thereof, in the viewing window 732b of the pluggable dual-connector SOC indicator 700, which is the charge status of the 20-volt battery.

At a step 1840, the second connector of pluggable dual-connector SOC indicator 700 is removed from the connector of the second type of battery or battery pack. For example, upon satisfactorily observing the charge status of the 20-volt battery, the user removes the voltage input jack 740b of the pluggable dual-connector SOC indicator 700 from the mating connector of the 20-volt battery.

Additionally, in method 1800, because the two portions of the pluggable dual-connector SOC indicator 700 operate separately and independently, the steps 1815, 1820, and 1825 can be performed at substantially the same time as the steps 1830, 1835, and 1840. Namely, the charge status of both the 24-volt battery and the 20-volt battery can be observed at substantially the same time.

Accordingly, one aspect of the presently disclosed pluggable SOC indicators, such as the pluggable single-connector SOC indicator 100, the pluggable dual-connector SOC indicator 200, the pluggable quad-connector SOC indicator 300, and the pluggable dual-connector SOC indicator 700, is that they are under power only when plugged into the battery or battery pack to be monitored. Therefore, the presently disclosed pluggable SOC indicators present a load or drain on the battery or battery pack to be monitored only during the brief period of time in which they are plugged in and the user is observing the charge status.

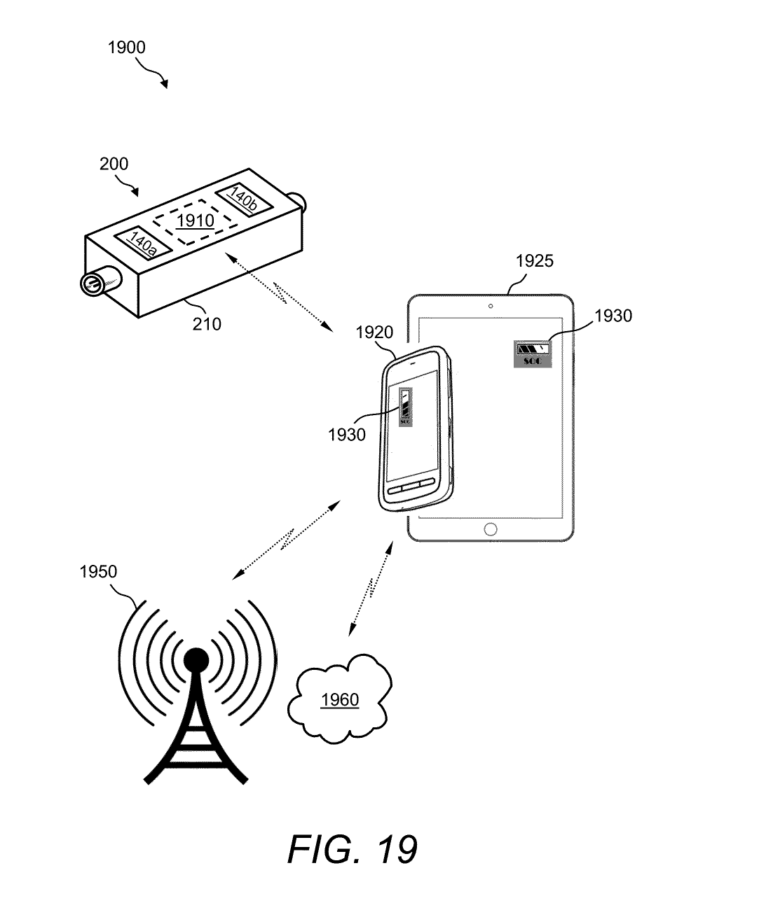

FIG. 19 illustrates a block diagram of an example of an SOC system 1900 that includes a mobile application for use with the presently disclosed pluggable SOC indicators. The SOC system 1900 includes at least one of any of the presently disclosed pluggable SOC indicators (e.g., pluggable single-connector SOC indicator 100 of FIG. 1, pluggable dual-connector SOC indicator 200 of FIG. 2, or pluggable quad-connector SOC indicator 300 of FIG. 3). For example, FIG. 19 shows the pluggable dual-connector SOC indicator 200, wherein the pluggable dual-connector SOC indicator 200 includes a communications interface 1910.

The communications interface 1910 may be any wired and/or wireless communication interface for connecting to a network and by which information may be exchanged with other devices connected to the network. Examples of wired communication interfaces may include, but are not limited to, USB ports, RS232 connectors, RJ45 connectors, Ethernet, and any combinations thereof. Examples of wireless communication interfaces may include, but are not limited to, an Intranet connection, Internet, ISM, Bluetooth® technology, Wi-Fi, Wi-Max, IEEE 802.11 technology, radio frequency (RF), Infrared Data Association (IrDA) compatible protocols, Local Area Networks (LAN), Wide Area Networks (WAN), Shared Wireless Access Protocol (SWAP), any combinations thereof, and other types of wireless networking protocols.

The communications interface 1910 can be used to communicate, preferably wirelessly, with mobile devices, such as but not limited to, a mobile phone 1920 or a tablet device 1925. The mobile phone 1920 can be any mobile phone that (1) is capable of running mobile applications and (2) is capable of communicating with the presently disclosed pluggable SOC indicators. The mobile phone 1920 can be, for example, an Android™ phone, an Apple iPhone, or a Samsung Galaxy phone. Likewise, the tablet device 1925 can be any tablet device that (1) is capable of running mobile applications, (2) is capable of communicating with the presently disclosed pluggable SOC indicators, and (3) has cellular network capability. The tablet device 1925 can be, for example, the 3G or 4G version of the Apple iPad.

Further, in SOC system 1900, the mobile phone 1920 and/or the tablet device 1925 can be in communication with a cellular network 1950 and/or a network 1960. The network 1960 can be any network for providing wired or wireless connection to the Internet, such as a local area network (LAN) or a wide area network (WAN).

An SOC mobile application 1930 is installed and running at the mobile phone 1920 and/or the tablet device 1925. The SOC mobile application 1930 is implemented according to the type (i.e., the operating system) of mobile phone 1920 and/or tablet device 1925 on which it is running. The SOC mobile application 1930 is designed to receive SOC information from the presently disclosed pluggable SOC indicators (e.g., pluggable single-connector SOC indicator 100 of FIG. 1, pluggable dual-connector SOC indicator 200 of FIG. 2, or pluggable quad-connector SOC indicator 300 of FIG. 3). Then, the SOC mobile application 1930 indicates graphically, audibly, and/or tactilely, the state of charge to the user (not shown).

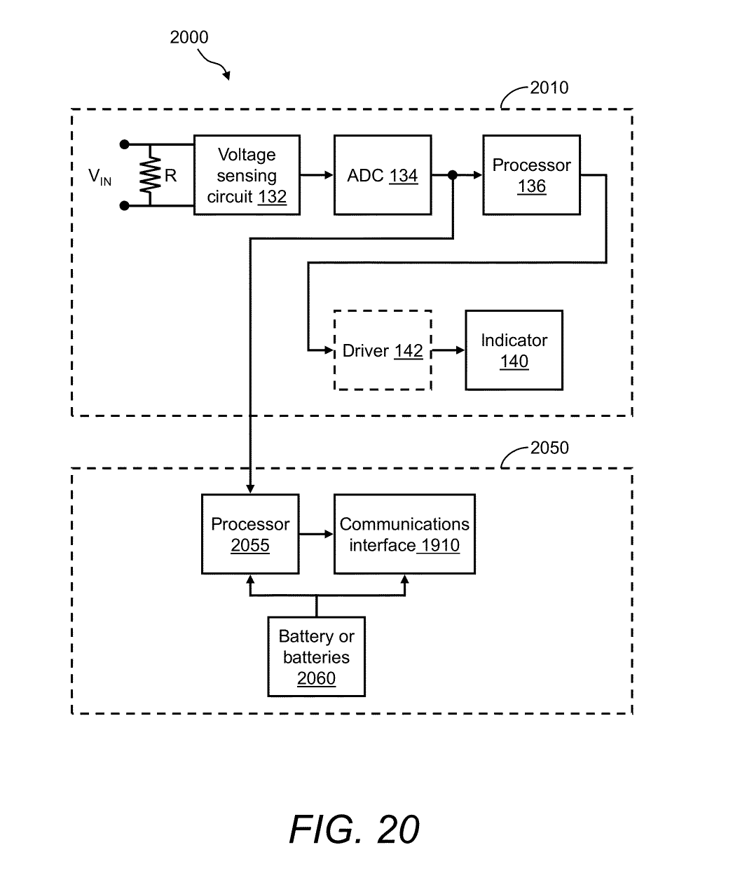

FIG. 20 illustrates a block diagram of an example of control electronics 2000 of the presently disclosed pluggable SOC indicators that is capable of communicating with the SOC mobile application 1930. In this example, the control electronics 2000 includes an SOC portion 2010 and a communications portion 2050. The SOC portion 2010 is substantially the same as the control electronics 130 shown in FIG. 4. The communications portion 2050 handles the communication of the SOC information to the SOC mobile application 1930 at, for example, the mobile phone 1920 and/or the tablet device 1925.

The communications portion 2050 includes a processor 2055 that is communicatively connected to the communications interface 1910. The digital output of the ADC 134 of the SOC portion 2010, which is the SOC information, feeds an input to the processor 2055. The processor 2055 can be any controller, microcontroller, or microprocessor that is capable of processing program instructions. One or more batteries 2060 provide power to the processor 2055 and the communications interface 1910. The one or more batteries 2060 can be any standard cylindrical battery, such as quadruple-A, triple-A, or double-A, or a battery from the family of button cell and coin cell batteries. A specific example of a battery 2060 is the CR2032 coin cell 3-volt battery.

In control electronics 2000, the SOC portion 2010 and the communications portion 2050 operate substantially independent of one another. Namely, the communications portion 2050 is powered separately from the SOC portion 2010 so that the communications portion 2050 is not dependent on the presence of the input voltage V_{IN} at the SOC portion 2010 for power. Therefore, in this example, the communications portion 2050 can transmit information to the SOC mobile application 1930 at any time, even when not plugged into, for example, the battery or battery pack 1610. However, in order to conserve battery life, the processor 2055 can be programmed to be in sleep mode when no voltage is detected at the input voltage V_{IN} at the SOC portion 2010 and to wake up when an input voltage V_{IN} is detected. Further, the SOC mobile application 1930 can be programmed to pull SOC information from control electronics 2000 periodically, such as every hour, regardless of the state of input voltage V_{IN}.

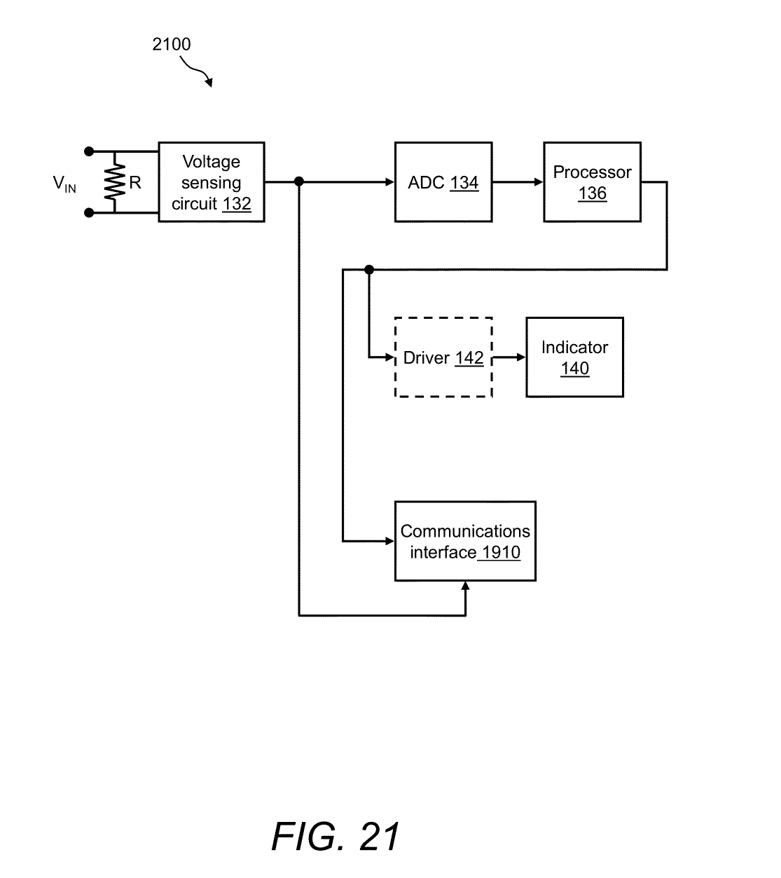

FIG. 21 illustrates a block diagram of another example of control electronics 2100 of the presently disclosed pluggable SOC indicators that is capable of communicating with the SOC mobile application 1930. In this example, the operation of the communications interface 1910 is dependent on the presence of a voltage at input voltage V_{IN}. For example, the operation of communications interface 1910 is dependent on the presently disclosed pluggable SOC indicators being plugged into, for example, the battery or battery pack 1610. This is because, in control electronics 2100, the communications interface 1910 is powered from the output of voltage sensing circuit 132. Further, the processor 136 provides the input (i.e., the SOC information) to the communications interface 1910. A drawback of the control electronics 2100 of FIG. 21 as compared with the control electronics 2000 of FIG. 20, is that it can transmit SOC information to the SOC mobile application 1930 only when in use, i.e., only when plugged into, for example, the battery or battery pack 1610.

Following long-standing patent law convention, the terms “a,” “an,” and “the” refer to “one or more” when used in this application, including the claims. Thus, for example, reference to “a subject” includes a plurality of subjects, unless the context clearly is to the contrary (e.g., a plurality of subjects), and so forth.

Throughout this specification and the claims, the terms “comprise,” “comprises,” and “comprising” are used in a non-exclusive sense, except where the context requires otherwise. Likewise, the term “include” and its grammatical variants are intended to be non-limiting, such that recitation of items in a list is not to the exclusion of other like items that can be substituted or added to the listed items.

For the purposes of this specification and appended claims, unless otherwise indicated, all numbers expressing amounts, sizes, dimensions, proportions, shapes, formulations, parameters, percentages, parameters, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some embodiments, ±100% in some embodiments ±50%, in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed methods or employ the disclosed compositions.

Further, the term “about” when used in connection with one or more numbers or numerical ranges, should be understood to refer to all such numbers, including all numbers in a range and modifies that range by extending the boundaries above and below the numerical values set forth. The recitation of numerical ranges by endpoints includes all numbers, e.g., whole integers, including fractions thereof, subsumed within that range (for example, the recitation of 1 to 5 includes 1, 2, 3, 4, and 5, as well as fractions thereof, e.g., 1.5, 2.25, 3.75, 4.1, and the like) and any range within that range.

Although the foregoing subject matter has been described in some detail by way of illustration and example for purposes of clarity of understanding, it will be understood by those skilled in the art that certain changes and modifications can be practiced within the scope of the appended claims.

That which is claimed:

1. An indicator device for monitoring a state of charge of one or more batteries or battery packs, the device comprising:
at least one voltage input connector configured to be electrically coupled to at least one voltage output connector of a battery or battery pack;
control electronics capable of measuring a voltage received from the at least one voltage input connector when the voltage input connector is electrically coupled to the at least one voltage output connector of the battery or battery pack to be monitored, and wherein the control electronics are configured to process an input voltage range and/or a battery discharge characteristic to determine a state of charge; and
at least one indicator which shows the state of charge, wherein the at least one voltage input connector, the control electronics, and the at least one indicator are in electronic communication; and
wherein the state of charge shown by the at least one indicator is related to the voltage measured by the control electronics.

2. The device of claim 1, wherein the at least one voltage input connector comprises a slip-on, non-locking connector configured to press fit onto the at least one voltage output connector of a battery or battery pack.

3. The device of claim 1, wherein the at least one voltage input connector comprises a male connector and the at least one voltage output connector comprises a female connector.

4. The device of claim 1, wherein the at least one voltage input connector comprises a female connector and the at least one voltage output connector comprises a male connector.

5. The device of claim 1, wherein the indicator is selected from the group consisting of a visual indicator, an audible indicator, and a tactile indicator.

6. The device of claim 5, wherein the visual indicator is selected from the group consisting of a liquid crystal display (LCD) and one or more light-emitting diodes (LEDs).

7. The device of claim 6, wherein the LCD is selected from the group consisting of a 5-bar LCD and a seven segment numeric LCD.

8. The device of claim 5, wherein the audible indicator comprises an audible speaker capable of producing one or more distinctive sounds.

9. The device of claim 8, wherein the one or more distinctive sounds is selected from the group consisting of a beeping sound and a vibration sound.

10. The device of claim 5, wherein the tactile indicator is selected from a vibration and a set of pins.

11. The device of claim 1, wherein the control electronics comprise one or more components selected from the group consisting of a voltage sensing circuit, an analog-to-digital converter (ADC), a processor, and optionally a driver.

12. The device of claim 11, wherein the voltage sensing circuit is capable of sensing any direct current (DC) voltage ranging from about 0 volts DC to about 50 volts DC.

13. The device of claim 11, wherein the voltage sensing circuit comprises one or more amplification or de-amplification functions for generating an analog voltage that correlates to an amplitude of the input voltage.

14. The device of claim 11, wherein the processor comprises internal programmable functions for
programming an expected range of an input voltage V_{IN}, and
correlating a value of the input voltage V_{IN} to the state of charge shown by the indicator.

15. The device of claim 11, wherein the processor drives the indicator directly.

16. The device of claim 11, wherein the driver is in electronic communication with the control electronics and the indicator.

17. The device of claim 1, further comprising a housing adapted to house the at least one voltage input connectors, the control electronics, and the at least one indicator.

18. The device of claim 1, further comprising between one and four voltage input connectors, wherein the between one and four voltage input connectors are each in electronic communication with between one and four corresponding sets of control electronics and between one and four corresponding indicators.

19. The device of claim 18, wherein each separate indicator in electronic communication with its voltage input connector operates independently.

20. A device for monitoring and communicating a state of charge of one or more batteries or battery packs, the device comprising:
at least one voltage input connector configured to be electrically coupled to at least one voltage output connector of a battery or battery pack;
control electronics capable of measuring a voltage received from the at least one voltage input connector when the voltage input connector is electrically coupled to the at least one voltage output connector of the battery or battery pack to be monitored, and wherein the control electronics are configured to process an input voltage range and/or a battery discharge characteristic to determine a state of charge, wherein the state of charge is related to the voltage measured by the control electronics; and
a communications interface configured to communicate information related to the state of charge to a network.

21. The device of claim 20, wherein the communications interface is coupled to the network through a wired interface.

22. The device of claim 20, wherein the communications interface is coupled to the network through a wireless interface.

23. The device of claim 20, wherein the network comprises a cellular network.

24. The device of claim 20, wherein the communications interface is configured to communicate with a mobile device coupled to the network.

25. The device of claim 20, wherein the communications interface is powered by the battery or battery pack to be monitored.

26. The device of claim 20, wherein the communications interface further comprises a processor.

27. The device of claim 20, wherein the communications interface further comprises one or more communications interface batteries adapted to power the communications interface.
